(19) United States
(12) Patent Application Publication
(10) Pub. No.: US 2023/0361096 A1
(43) Pub. Date: Nov. 9, 2023

(54) PACKAGE-ON-PACKAGE AND SYSTEM-IN-PACKAGE PACKAGING ARCHITECTURES

(71) Applicant: Lumentum Operations LLC, San Jose, CA (US)

(72) Inventors: Wei SHI, San Jose, CA (US); Kevin WANG, Fremont, CA (US); Michael MILLER, Ottawa (CA); Steve CHUENG, San Jose, CA (US); Mikhail DOLGANOV, San Jose, CA (US); Lijun ZHU, Dublin, CA (US)

(21) Appl. No.: 18/068,252

(22) Filed: Dec. 19, 2022

Related U.S. Application Data
(60) Provisional application No. 63/364,259, filed on May 5, 2022.

(51) Int. Cl. H01L 25/16; H01S 5/183; H01S 5/02208; H01S 5/02253; H01S 5/02315; H01S 5/0239; H01S 5/026

(52) U.S. Cl. CPC H01L 25/167; H01L 25/165; H01S 5/18388; H01S 5/02208; H01S 5/02253; H01S 5/02315; H01S 5/0239; H01S 5/0261; H01S 5/02257

(57) ABSTRACT

An optical package may include a fan-out-wafer-level-packaging (FOWLP) sub-package including a redistribution layer (RDL) on a molded component including an electrical chip. The optical package may include an optical chip over the FOWLP sub-package. The optical chip may be electrically connected to the RDL. An area of a surface of the RDL may be larger than an area of a surface of the optical chip. The optical package may include a package housing over the optical chip such that light to be received or transmitted by the optical chip may is to pass through the package housing.

### CROSS-REFERENCE TO RELATED APPLICATION

This Patent application claims priority to U.S. Provisional Patent Application No. 63/364,259, filed on May 5, 2022, and entitled “PACKAGING ARCHITECTURES FOR A THREE-DIMENSIONAL SENSING PROJECTOR OR CAMERA.” The disclosure of the prior Application is considered part of and is incorporated by reference into this Patent Application.

### TECHNICAL FIELD

The present disclosure relates generally to packaging architectures for an optical package and, more particularly, to package-on-package (PoP) and system-in-package (SiP) packaging architectures for an optical package.

### BACKGROUND

Wafer level packaging (WLP) is a type of packaging technology that is performed at wafer level. This means that the packaging is applied on whole wafers and wafers are diced only after packaging is completed. In addition to size and cost benefits, WLP offers integration of wafer fabrication and wafer testing at the wafer level, which facilitates a streamlined manufacturing process. A WLP typically includes a redistribution layer (RDL) that is used in association with rearranging or spreading contacts of the die. One type of WLP is fan-in WLP (FIWLP). In the case of an FIWLP package, an area of a surface of an RDL is the same as an area of a surface of a die. Another type of WLP is fan-out WLP (FOWLP). In an FOWLP package, an area of a surface of an RDL is larger than an area of a surface of a die.

### SUMMARY

In some implementations, an optical package includes an FOWLP sub-package including an RDL on a molded component including an electrical chip; an optical chip over the FOWLP sub-package, the optical chip being electrically connected to the RDL 210, wherein an area of a surface of the RDL is larger than an area of a surface of the optical chip; and a package housing over the optical chip, wherein light to be received or transmitted by the optical chip is to pass through the package housing.

In some implementations, an optical package includes an FOWLP sub-package including an RDL on a first molded component; a molded interconnect substrate (MIS) sub-package over the FOWLP sub-package, the MIS sub-package including a second RDL on a second molded component; an optical chip over the FOWLP sub-package, the optical chip being electrically connected to the first RDL, wherein an area of the RDL is larger than an area of the optical chip; and a package housing over the VCSEL chip, wherein light to be received or transmitted by the optical chip is to pass through the package housing.

In some implementations, an optical package includes an FOWLP sub-package including an RDL on a molded component, wherein the molded component includes at least one electrical chip; a vertical-cavity surface-emitting laser (VCSEL) chip over the FOWLP sub-package, the VCSEL chip being electrically connected to the electrical through the RDL, wherein a size of the RDL is larger than a corresponding size of the VCSEL chip; and a package housing over the VCSEL chip, wherein light to be transmitted by the VCSEL chip is to pass through the package housing.

### BRIEF DESCRIPTION OF THE DRAWINGS

FIG. 1 is a diagram illustrating a conventional optical package in which a VCSEL chip is stacked on an FIWLP sub-package that is arranged on a relatively large packaging substrate.

FIGS. 2A and 2B are diagrams illustrating example implementations of an optical package in the form of an optical transmitter that includes an FOWLP sub-package comprising an RDL on a molded component, and a VCSEL chip over the FOWLP sub-package.

FIG. 3 is a diagram illustrating various techniques by which emitters of a VCSEL chip can be electrically connected to the RDL.

FIGS. 4A-4C are diagrams illustrating example implementations of the optical package in the form of an optical transmitter including various sets of optical components.

FIGS. 5A-5D are diagrams illustrating example implementations of the optical package in the form of an optical transmitter in which the VCSEL chip is included in a second sub-package.

FIGS. 6A-6F are diagrams illustrating additional example implementations of the optical package in the form of an optical transmitter.

FIG. 7 is a diagram illustrating an example implementation of the optical package in the form of an optical transmitter in which the FOWLP sub-package includes multiple integrated circuit (IC) driver chips.

FIGS. 8A and 8B are diagrams illustrating example implementations of optical packages in the form of an optical transmitter including multiple VCSEL chips to form a multi-chip module.

FIGS. 9A-9H are diagrams illustrating various example implementations of an optical package in the form of an optical receiver that includes an FOWLP sub-package comprising an RDL on a molded component, and a sensor chip over the FOWLP sub-package.

FIGS. 10A and 10B are diagrams illustrating example implementations of optical packages that form a three-dimensional (3D) sensing module.

### DETAILED DESCRIPTION

The following detailed description of example implementations refers to the accompanying drawings. The same reference numbers in different drawings may identify the same or similar elements.

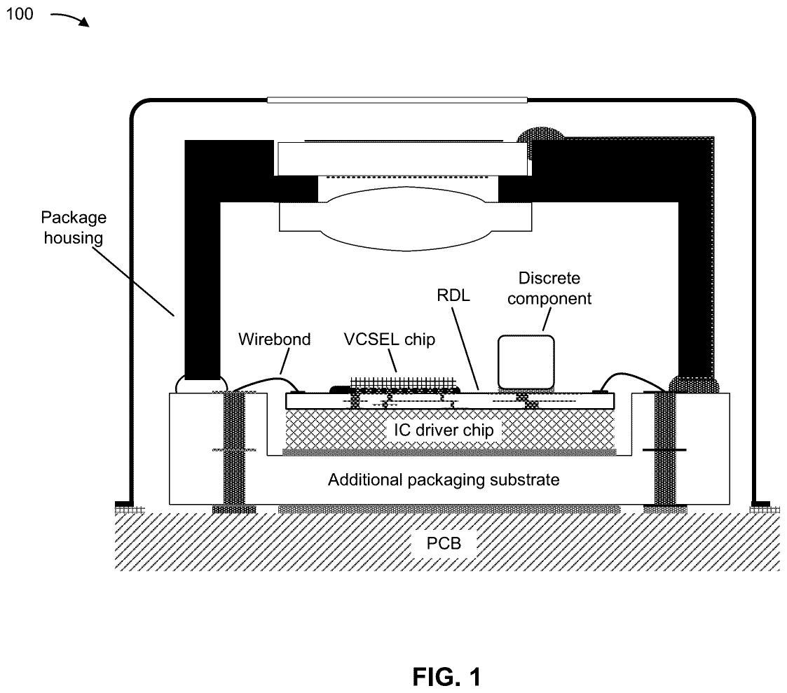

A size of an optical package is a significant consideration with respect to optical package design. For example, in some applications, such as a 3D sensing projector or camera, a size of an optical package may need to be minimized in order to satisfy a size constraint. Another design consideration is maintenance of signal integrity within the optical package. In some cases, signal degradation may be reduced by reducing a length of wirebonds in the optical package. In an example, an optical package may include a VCSEL chip stacked on a redistribution layer (RDL) and an IC driver chip that are arranged on a relatively large packaging substrate (e.g., a quad-flat-no-lead (QFN) substrate, a cavity high temperature co-fired ceramic (cavity-HTCC) substrate, or the like). Here, inputs and outputs (I/Os) of the IC driver chip are electrically connected to the packaging substrate and other components (via the RDL) by relatively long wirebonds. In some scenarios, it is desirable to reduce the size of the optical package or reduce a length of (or eliminate the use of) wirebonds within the optical package (e.g., to improve signal integrity). FIG. 1 is a diagram illustrating an optical package in which a VCSEL chip is stacked on an FIWLP sub-package (including an IC driver chip) that is arranged on a relatively large packaging substrate (e.g., a QFN substrate or a cavity-HTCC substrate). As shown in FIG. 1, I/Os of the IC driver chip are electrically connected to the substrate and other components (via the RDL) by relatively long wirebonds.

Additionally, as noted above and as shown in FIG. 1, an optical package including a VCSEL chip stacked on an IC driver chip may include an RDL, for providing circuit routing, that is formed using fan-in wafer-level-packaging (FIWLP) technology. In such an FIWLP package, as illustrated in FIG. 1, an area on which other circuit components (e.g., one or more capacitors, one or more thermistors, one or more photodiodes (PDs), or the like) can be mounted is the same as an area of the IC driver chip (i.e., the area of the RDL matches the area of the IC driver chip). Thus, when there are comparatively more components to mount, the area of the IC driver chip may be insufficient to permit mounting of at least some components. Notably, with FIWLP technology, the RDL typically includes only two or three metal layers due to manufacturing constraints, and forming more than three metal layers using FIWLP technology is difficult or impossible. However, FOWLP technology facilitates formation of a higher number of metal layers (e.g., more than three metal layers), meaning that circuit routing capability can be increased with FOWLP technology.

Some implementations described herein provide architectures for an improved optical package. The improved optical package includes an FOWLP sub-package having an RDL on a molded component, with the molded component including one or more components, such as one or more IC driver chips, a capacitor array, or one or more circuit components (e.g., one or more capacitors, one or more thermistors, or the like). The improved optical package further includes a VCSEL chip over the FOWLP sub-package, with the VCSEL chip being electrically connected to the RDL of the FOWLP sub-package. The optical package further includes a package housing over the FOWLP sub-package and the VCSEL chip. Additional details and example implementations are provided below.

In some implementations, a size (e.g., a radius, a width, a length, a height, an area, a volume, or the like) of the improved optical package is reduced and an area for mounting other components is increased (e.g., as compared to a conventional optical package including an FIWLP sub-package, as illustrated in FIG. 1). Further, the improved optical package can reduce or eliminate a need for wirebonds, thereby providing a further reduction in package size and improving optical signal integrity. Additionally, the improved optical package does not require an additional (large) packaging substrate, meaning that a backside of the IC driver chip can be exposed, thereby reducing thermal resistance (e.g., as compared to a conventional optical package that includes a packaging substrate, as illustrated in FIG. 1). Further, because the FOWLP sub-package included in the improved optical package has a surface with an area that is larger than an area of a surface of the driver chip, the package housing can in some implementations be mounted on the FOWLP sub-package or on a molded interconnect substrate (MIS) sub-package that is mounted on the FOWLP sub-package (e.g., rather than being mounted on a printed circuit board (PCB) after wafer dicing), which simplifies manufacturing and provides further size reduction.

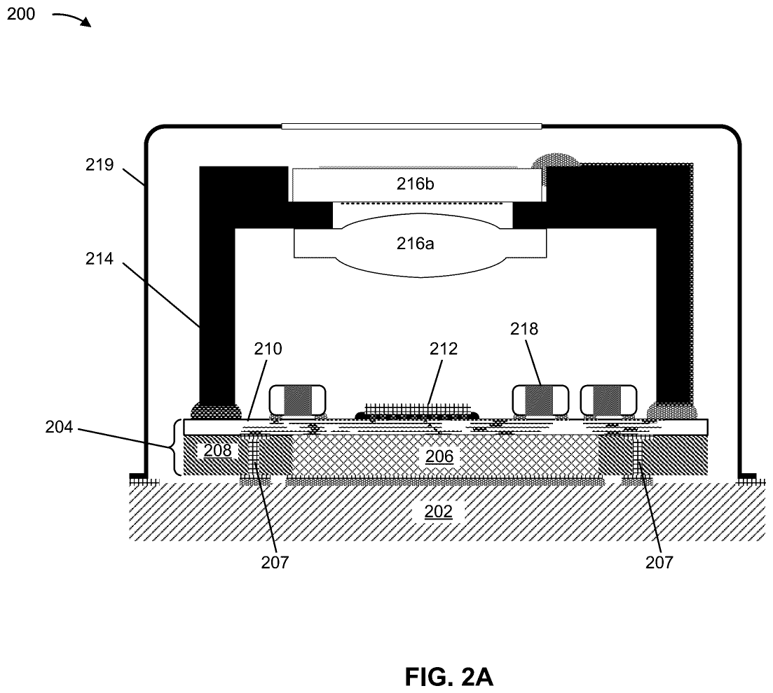

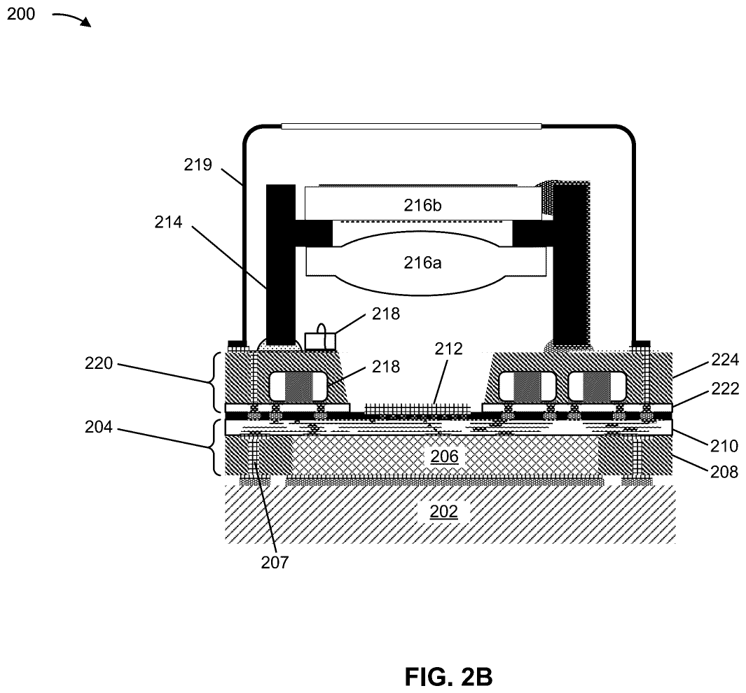

FIGS. 2A and 2B are diagrams illustrating example implementations of an optical package 200 in the form an optical transmitter (e.g., a projector) that includes an FOWLP sub-package comprising an RDL on a molded component, and a VCSEL chip over the FOWLP sub-package.

In an example implementation shown in FIG. 2A, the optical package 200 includes a PCB 202, an FOWLP sub-package 204 (including an electrical chip, in the form of an IC driver chip 206, embedded in a molded component 208, and an RDL 210), an optical chip in the form of a VCSEL chip 212, a package housing 214, and a set of optical components 216 (e.g., a collimating lens 216a and a diffractive optical element (DOE) 216b are shown in FIG. 2A), a set of circuit components 218, and an electromagnetic interference (EMI) shield 219.

The PCB 202 is a substrate on or over which other components of the optical package 200 are mounted (e.g., after assembly of other components of the optical package and wafer dicing).

The FOWLP sub-package 204 is a package formed using FOWLP technology. As shown in FIG. 2A, the FOWLP sub-package 204 may comprise the RDL 210 and the molded component 208, with the IC driver chip 206 driver being embedded in the molded component 208. As illustrated in FIG. 2A, and as noted above, the use of FOWLP technology enables an area of a surface of RDL 210 to be larger than an area of a surface of the IC driver chip 206. That is, the use of FOWLP technology to form the FOWLP sub-package 204 enables the surface of the RDL 210 to extend (laterally) beyond the surface of the IC driver chip 206. In this way, the use of FOWLP technology enables the RDL 210 to be designed or configured to, for example, provide electrical connections for one or more components (e.g., the VCSEL chip 212, one or more circuit components 218, or the like) to the substrate 202 or provide an area on which one or more components (e.g., the VCSEL chip 212, one or more circuit components 218, the package housing 214, or the like) can be mounted, while reducing overall package size.

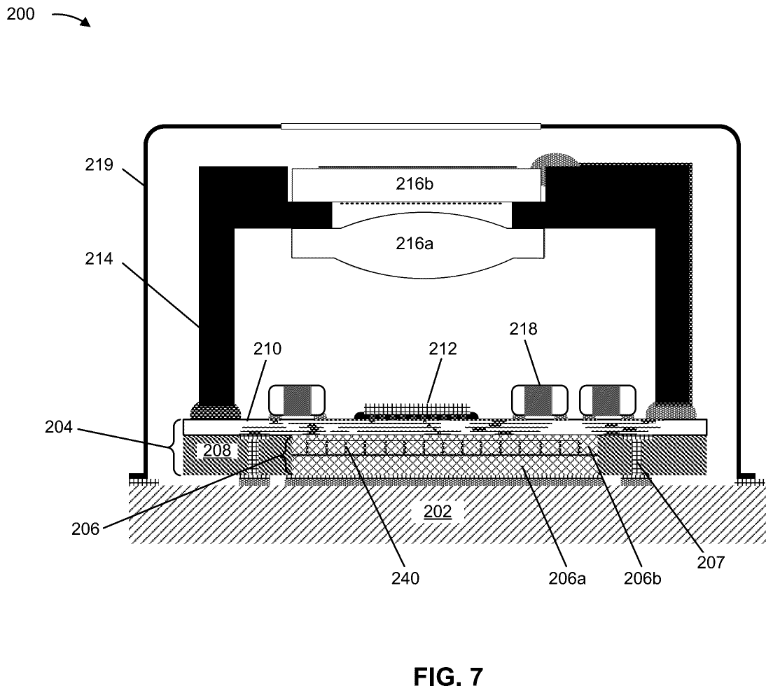

The IC driver chip 206 is a component that drives or otherwise controls the VCSEL chip 212. In some implementations, the IC driver chip 206 is electrically connected to the VCSEL chip 212 or one or more other circuit components 218 of the optical package 200 through the RDL 210. In some implementations, the IC driver chip 206 may be included in (e.g., embedded in) the molded component 208 of the FOWLP sub-package 204. In some implementations, multiple IC driver chips 206 may be embedded in the molded component 208, an example of which is described below with respect to FIG. 7.

The molded component 208 is a component of the FOWLP sub-package 204 in which one or more components of the optical package 200 are embedded (i.e., molded). In some implementations, the molded component 208 may comprise an epoxy molding compound (EMC). In some implementations, as shown in FIG. 2A, the IC driver chip 206 may be embedded in the molded component 208. Additionally, or alternatively, the molded component 208 may comprise one or more components other than a single IC driver chip 206. For example, the molded component 208 may include two or more IC driver chips 206, a capacitor array, or one or more discrete circuit components (e.g., one or more capacitors, one or more thermistors, or the like), as described with respect to various examples herein.

The RDL 210 is a component of the FOWLP sub-package 204 that provides circuit routing for the optical package 200. The RDL 210 may be a metal interconnect (e.g., copper traces) within semiconductor (or other materials) that provides electrical connections between different electrodes in one part of a semiconductor package to another part of the semiconductor package. The RDL 210 may be layers of wiring interconnects that redistribute electrical I/O access from a chip, die, or other components to different parts of a package. The RDL 210 may provide metal interconnects three-dimensionally. The RDL 210 may be located below a set of components, connect to a variety of electrical pins of the set of components and distribute electrical connectivity through its metal interconnects laterally and/or vertically to other components. The RDL 210 may distribute electrical connectivity in a way that makes it easier to add micro-bumps to a die or to align electrical connectivity from the set of components with electrical connectivity of other components. The VCSEL chip 212 is electrically connected to the RDL 210 such that the VCSEL chip 212 can be electrically driven by the IC driver chip 206. As indicated in FIG. 2A and noted above, the use of FOWLP technology facilitates formation of a high number of metal layers (e.g., more than three metal layers) in the RDL 210. As a result, a circuit routing capability of the RDL 210 is increased (e.g., as compared to an RDL in a conventional optical package including an FIWLP sub-package). In some implementations, as illustrated in FIG. 2A, a size (e.g., a surface area, a width, a length, or the like) of the RDL 210 is larger than a corresponding size of the IC driver chip 206. In some implementations, a size (e.g., a surface area, a width, a length, or the like) of the RDL 210 matches a corresponding size of the molded component 208. In some implementations, the use of FOWLP technology to form the FOWLP sub-package 204 enables the surface of the RDL 210 to extend (laterally) beyond the surface of the IC driver chip 206 (e.g., such that the size of the RDL 210 matches the size of the molded component 208). Thus, the use of FOWLP technology for forming the FOWLP sub-package 204 including the RDL 210 can enable the RDL 210 to provide electrical connections for the VCSEL chip 212 and/or for one or more circuit components 218. Further, the use of FOWLP technology for forming the FOWLP sub-package 204 can enable the package housing to be mounted on the RDL 210 such that the molded component 208 (below the RDL 210) provides structural support for the package housing 214. Thus, in some implementations, the use of FOWLP technology to form the FOWLP sub-package 204 enables the VCSEL chip 212, one or more circuit components 218, and/or the package housing 214 to be mounted on or over or formed on or over the RDL 210. In some implementations, the RDL 210 is supported by the molded component 208 and is electrically connected to the PCB 202 through the molded component 208 (e.g., rather than via wirebonds). In some implementations, the RDL 210 may be electrically connected to the molded component 208 on a side or a surface that is opposite from a side or a surface on which the RDL 210 is electrically connected the VCSEL chip 212 and/or one or more circuit components 218.

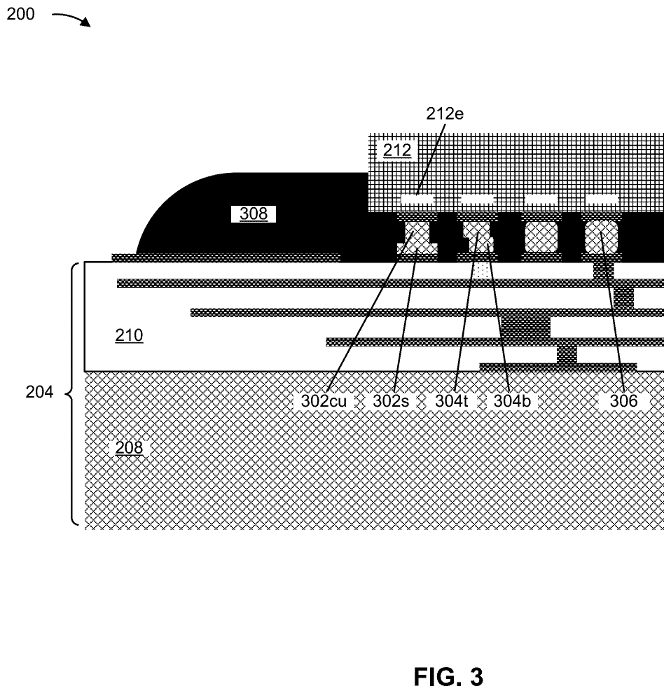

The VCSEL chip 212 is a component including an array of emitters (e.g., a one-dimensional (1D) VCSEL array, a two-dimensional (2D) VCSEL array, or the like). As illustrated in FIG. 2A, the VCSEL chip 212 is arranged over the FOWLP sub-package 204. In some implementations, the VCSEL chip 212 is electrically connected to the RDL 210 to enable the VCSEL chip 212 to be driven or controlled by the IC driver chip 206 included in the FOWLP sub-package 204. Here, the VCSEL chip 212 is electrically connected to the RDL 210 without wirebonds. Additional details regarding the electrical connection of the VCSEL chip 212 to the RDL 210 are described below with respect to FIG. 3. In some implementations, an underfill layer is formed between physical connections (e.g., bonds) that electrically connect the VCSEL chip 212 to the RDL 210. Techniques for connecting the VCSEL chip 212 and the RDL 210 are described below with respect to FIG. 3.

The package housing 214 is a housing that supports the set of optical components 216 of the optical package and provides protection for other components of the optical package 200. For example, as shown in FIG. 2A, the package housing 214 may support a collimating lens 216a and a diffractive optical element 216b. In some implementations, as illustrated in FIG. 2A, the package housing 214 is affixed to the FOWLP sub-package 204. Alternatively, in some implementations, the package housing 214 is affixed to an MIS sub-package that is on the FOWLP sub-package 204, as illustrated by various examples described herein.

The set of optical components 216 of the optical package 200 includes one or more components associated with controlling, directing, or otherwise manipulating light emitted by the VCSEL chip 212. For example, the set of optical components 216 may include a collimating lens 216a and a DOE 216b, as illustrated in FIG. 2A. As other examples, the set of optical components 216 may include one or more of a microlens array (MLA), a rotational offset MLA (roMLA), a glass window, a coating (e.g., an indium titanium oxide (ITO) coating), or a protective window, as illustrated by various examples described herein.

The set of circuit components 218 includes one or more discrete circuit components, such as one or more capacitors or one or more thermistors, or one or more PDs, among other examples. In some implementations, as illustrated in FIG. 2A, a circuit component 218 may be mounted on a surface of the FOWLP sub-package 204 (e.g., on a surface of the RDL 210) and electrically connected to RDL 210. Notably, due to the use of FOWLP technology, an area of the surface of the RDL 210 is increased and, therefore, an available area on which to mount circuit components 218 of the optical package 200 is increased (e.g., as compared to a conventional optical package including an FIWLP sub-package).

The EMI shield 219 is a component to shield other components of optical package 200 from EMI. In some implementations, as shown in FIG. 2A, the EMI shield 219 includes a window through which light can be emitted from the optical package 200. In some implementations, as shown in FIG. 2A, the EMI shield 219 is affixed to the PCB 202. Alternatively, in some implementations, the EMI shield 219 is affixed to the FOWLP sub-package 204 or to an MIS sub-package that is on the FOWLP sub-package 204, as illustrated by various examples described herein.

The architecture shown in FIG. 2A—the stack of the VCSEL chip 212 on the FOWLP sub-package 204 including the IC driver chip 206—can be referred to as a system-in-package (SiP) architecture. One advantage of a SiP architecture such as that shown in FIG. 2A (as compared to the conventional optical package including an FIWLP sub-package) is the increased area on which to mount circuit components 218 (e.g., a higher quantity of circuit components 218 and/or physically larger circuit components 218), as noted above. Thus, for a given package size, the use of FOWLP technology enables a quantity of circuit components 218 (or the size of circuit components 218) that can be mounted in an optical package 200 with the SiP architecture to be greater (or larger) than that of a conventional optical package of a comparable package size. Another advantage of the SiP architecture is a capability to support a higher quantity of I/Os (e.g., multiple rows of I/Os can be supported using through-mold-vias (TMVs)). In the SiP architecture shown in FIG. 2A, TMVs 207 (e.g., copper (Cu) vias) are illustrated passing through the molded component 208 to the left and the right of the IC driver chip 206. Thus, the TMVs 207 can provide a vertical connection between a top surface of the molded component 208 and a bottom surface of the molded component 208 (e.g., so that wirebonds are not needed in association with electrically connect the IC driver chip 206 to the PCB 202). Another advantage of the SiP architecture is a reduced package size (e.g., as compared to the conventional package with wirebonds to connect the IC driver chip 206 to the substrate). For example, a size of an optical package 200 including a given set of components may be smaller than a size of a conventional optical package including a comparable set of components. More particularly, the FOWLP sub-package 204 (including the RDL 210 on the IC driver chip 206 within the molded component 208 including the TMVs 207) provides electrical connection of the IC driver chip 206 and the VCSEL chip 212 to the substrate 202 (rather than such electrical connection by wirebonds), thereby enabling a reduced package size (e.g., since the FOWLP sub-package 204 negates need for wirebonds). Additionally, because the FOWLP sub-package 204 can provide electrical connection of the IC driver chip 206 and the VCSEL chip 212, and can accommodate mounting of the package housing 214, the FOWLP sub-package 204 performs the function of the packaging substrate in the conventional optical package, thereby enabling a reduced package size (e.g., since the FOWLP sub-package 204 negates a need for the packaging substrate). Further, because the FOWLP sub-package 204 negates a need for a packaging substrate, there is no gap between the packaging substrate and the IC driver chip 206, which enables further size reduction. In one particular example, a width, length, or diameter of the optical package 200 shown in FIG. 2A may be between approximately 0.6 millimeters (mm) and approximately 1.4 mm smaller than a corresponding size of the conventional optical package shown in FIG. 1. A height of the optical package 200 shown in FIG. 2A may also be reduced (e.g., since, in effect, the FOWLP sub-package 204 in the optical package 200 having the SiP architecture performs the function of the packaging substrate, thereby negating a need for the packaging substrate). That is, by performing the function of the packaging substrate, the FOWLP sub-package 204 eliminates a need for a large packaging substrate, meaning that a total package height of the optical package 200 shown in FIG. 2A is less than that of a total package height of the conventional optical package. A further advantage is that the SiP architecture does not utilize a packaging substrate (e.g., no QFN substrate or cavity-HTCC substrate is needed) and, therefore, thermal resistance of optical package 200 is reduced. Additionally, a cost of the optical package 200 shown in FIG. 2A may be reduced. For example, a fabrication cost of the optical package 200 having the SiP architecture may be less than that of an optical package that uses a flip-chip design or wirebond connections for a given package size and/or a given number of I/Os. As another example, the optical package 200 shown in FIG. 2A does not include a substrate, thereby reducing cost. As another example, fabrication of a FOWLP package may be cheaper than fabrication of an optical package including wire bonds.

In some implementations, the optical package 200 includes an MIS sub-package 220 over the FOWLP sub-package 204. FIG. 2B is a diagram of an example implementation of an optical package 200 that includes an MIS sub-package 220 over the FOWLP sub-package 204. As shown in FIG. 2B, the MIS sub-package 220 may include an RDL 222 and a molded component 224.

The RDL 222 is a layer to enable electrical connection of one or more circuit components 218 embedded in the molded component 224 to, for example, the IC driver chip 206. In some implementations, a size (e.g., a surface area, a width, a length, or the like) of the RDL 222 matches a corresponding size of the molded component 224. In some implementations, the RDL 222 provides structural support for one or more circuit components 218 and/or for the molded component 224. In some implementations, the RDL 222 is supported by the FOWLP sub-package 204 and is electrically connected to the RDL 210. In some implementations, the RDL 210 may be electrically connected to the one or more circuit components 218 on a side or a surface that is opposite from a side or a surface on which the RDL 222 is electrically connected the RDL 210. In some implementations, the RDL 222 may comprise a single metal layer (e.g., a Cu layer).

As shown, the molded component 224 may include one or more circuit components 218 (e.g., one or more capacitors, one or more thermistors, or the like). That is, one or more circuit components 218 may be embedded in the molded component 224 of the MIS sub-package 220.

As shown in FIG. 2B, the MIS sub-package 220 may be formed to allow the VCSEL chip 212 to be arranged in a cavity of the MIS sub-package 220. In some implementations, the MIS sub-package 220 may be affixed to the FOWLP sub-package 204 using solder balls, after which an underfill may be formed between the MIS sub-package 220 and the FOWLP sub-package 204. In some implementations, as illustrated in FIG. 2B, one or more circuit components 218 may be mounted on a surface of the MIS sub-package 220. In some implementations, as further illustrated in FIG. 2B, the package housing 214 and/or the EMI shield 219 can be mounted on the MIS sub-package 220 (e.g., rather than the PCB 202).

The architecture shown in FIG. 2B—the MIS sub-package 220 on the FOWLP sub-package 204 including the IC driver chip 206, with the stack of the VCSEL chip 212 on the FOWLP sub-package 204 including the IC driver chip 206—can be referred to as a package-on-package (PoP) architecture. That is, the MIS sub-package 220 on the FOWLP sub-package 204 (with the VCSEL chip 212 on the FOWLP sub-package 204) can be described as a PoP architecture. A number of characteristics differ between the SiP architecture shown in FIG. 2A the PoP architecture shown in FIG. 2B. For example, sides of the MIS sub-package 220 and the FOWLP sub-package 204 are not within the EMI shield 219) in the PoP architecture (as compared to being within the EMI shield 219 as in the SiP architecture). As another example, the PoP architecture of FIG. 2B includes a set of vias through the molded component 224 up to the EMI shield 219. As another example, an overall height of the EMI shield 219 in the PoP architecture may be less than that of the EMI shield 219 in the SiP architecture.

An advantage of a PoP architecture such as that shown in FIG. 2B (as compared to the conventional optical package including an FIWLP sub-package) is the increased area on which to mount circuit components 218 (e.g., a higher quantity of circuit components 218 and/or physically larger circuit components 218). Another advantage of the PoP architecture is a capability to support a higher quantity of I/Os. Another advantage of the PoP architecture is a reduced package size. For example, a size of an optical package 200 including a given set of components may be smaller than a size of a conventional optical package including a comparable set of components. More particularly, the FOWLP sub-package 204 provides electrical connection of the IC driver chip 206 and the VCSEL chip 212 to the substrate 202 (rather than such electrical connection by wirebonds), thereby enabling a reduced package size (e.g., since the FOWLP sub-package 204 negates need for wirebonds). Additionally, because the FOWLP sub-package 204 can provide electrical connection of the IC driver chip 206 and the VCSEL chip 212, and the MIS sub-package 220 can accommodate mounting of the package housing 214, the FOWLP sub-package 204 and MIS sub-package 220 collectively perform the function of the packaging substrate in the conventional optical package, thereby enabling a reduced package size. Further, because the FOWLP sub-package 204 and the MIS sub-package 220 negate a need for a packaging substrate, there is no gap between the packaging substrate and the IC driver chip 206, which enables further size reduction. In one particular example, a total width, length, or diameter of the optical package 200 shown in FIG. 2B may be between approximately 2.6 mm and approximately 3.4 mm smaller than a corresponding size of the conventional optical package shown in FIG. 1. In some implementations, some portion of this size reduction is provided by the capability to mount the package housing 214 and the EMI shield 219 on the MIS sub-package 220 (e.g., rather than the PCB 202), as illustrated in FIG. 2B. A height of the optical package 200 shown in FIG. 2B may also be reduced (e.g., since, in effect, the FOWLP sub-package 204 and the MIS sub-package 220 in the optical package 200 having the PoP architecture performs the function of the packaging substrate, thereby negating a need for the packaging substrate). That is, by performing the function of the packaging substrate, the FOWLP sub-package 204 and the MIS sub-package 220 eliminate a need for a large packaging substrate, meaning that a total package height of the optical package 200 shown in FIG. 2B is less than that of a total package height of the conventional optical package. A further advantage is that the PoP architecture does not utilize a packaging substrate and, therefore, thermal resistance of optical package 200 is reduced. Additionally, a cost of the optical package 200 shown in FIG. 2B may be reduced. For example, a fabrication cost of the optical package 200 with the PoP architecture may be less than that of an optical package that uses a flip-chip design or wirebond connections. As another example, the molding associated with forming the MIS sub-package 220 and the bonding of the set of circuit components 218 can be performed at the same time (e.g., using a pick-and-place assembly process). As another example, a size of the package housing 214 and/or the EMI shield 219 in the optical package 200 with the PoP architecture may reduced, thereby reducing material cost of the optical package 200 with the PoP architecture.

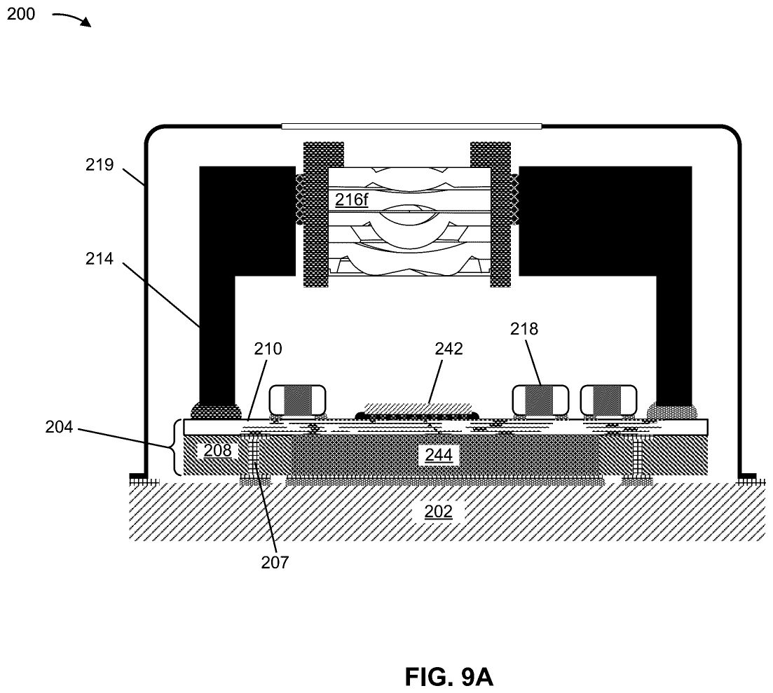

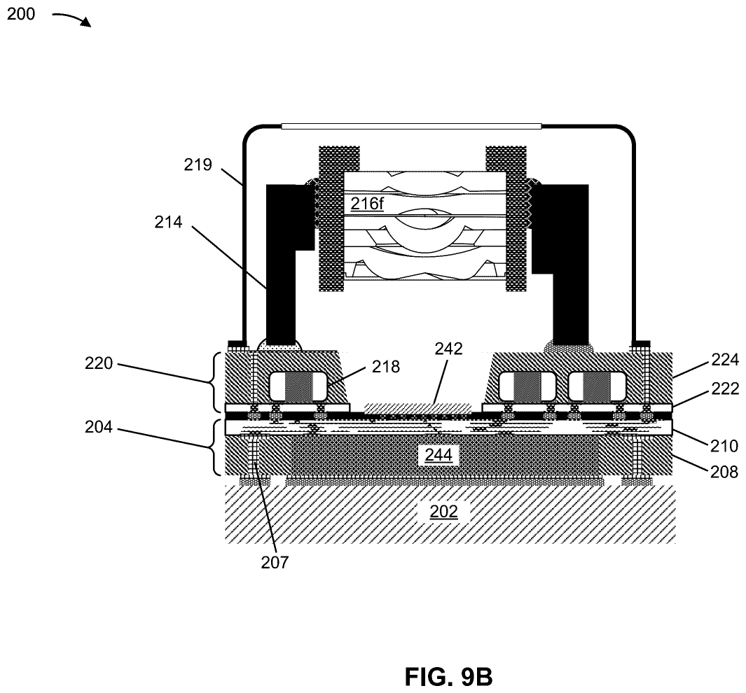

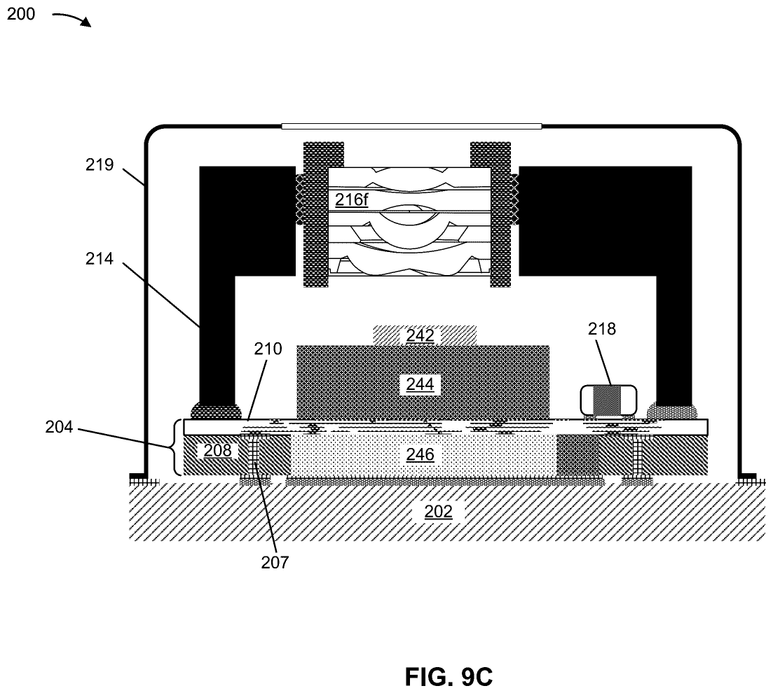

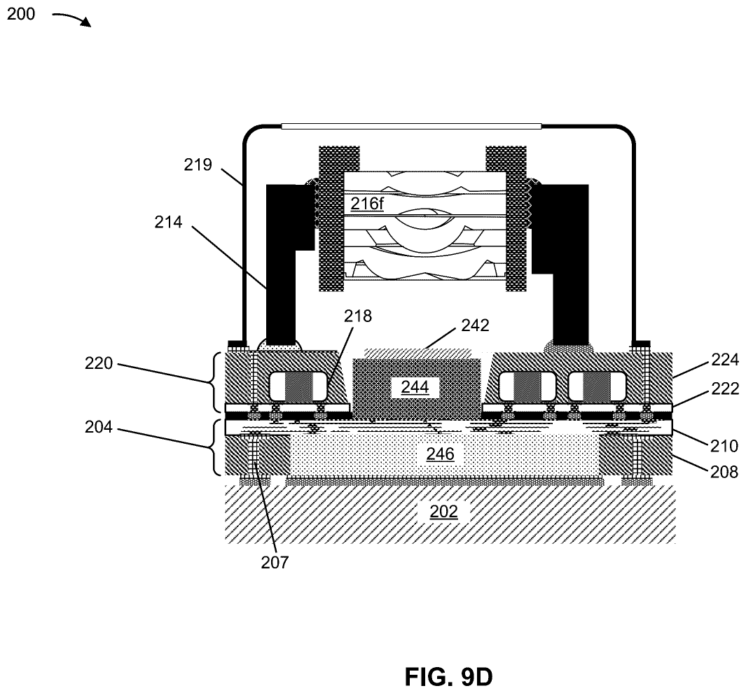

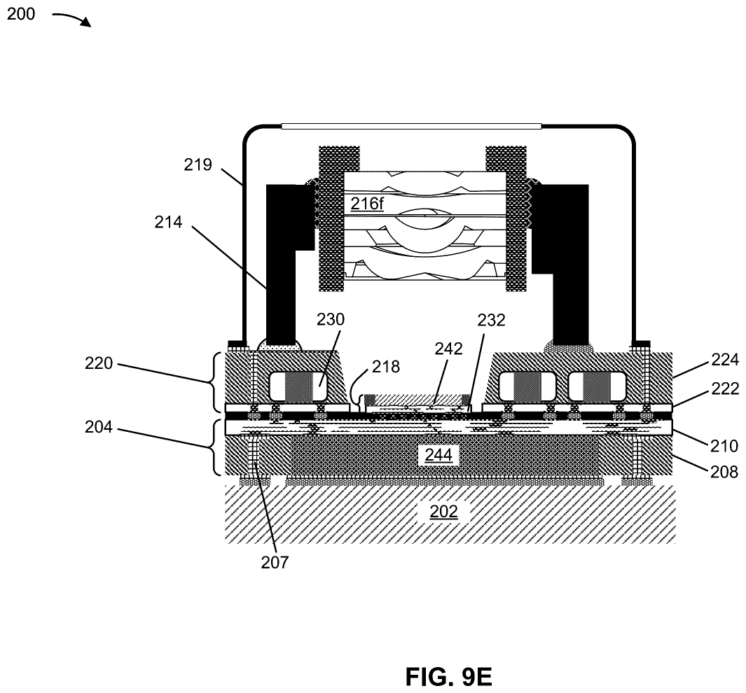

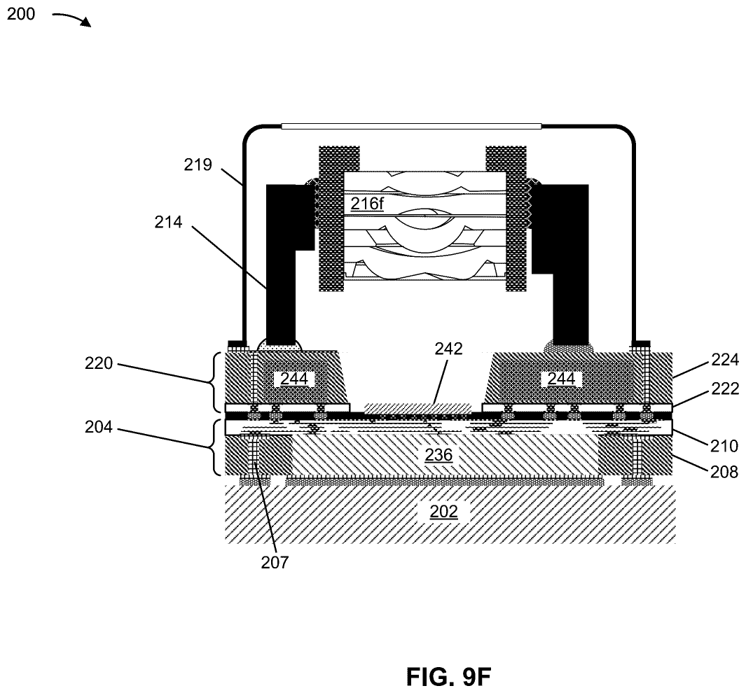

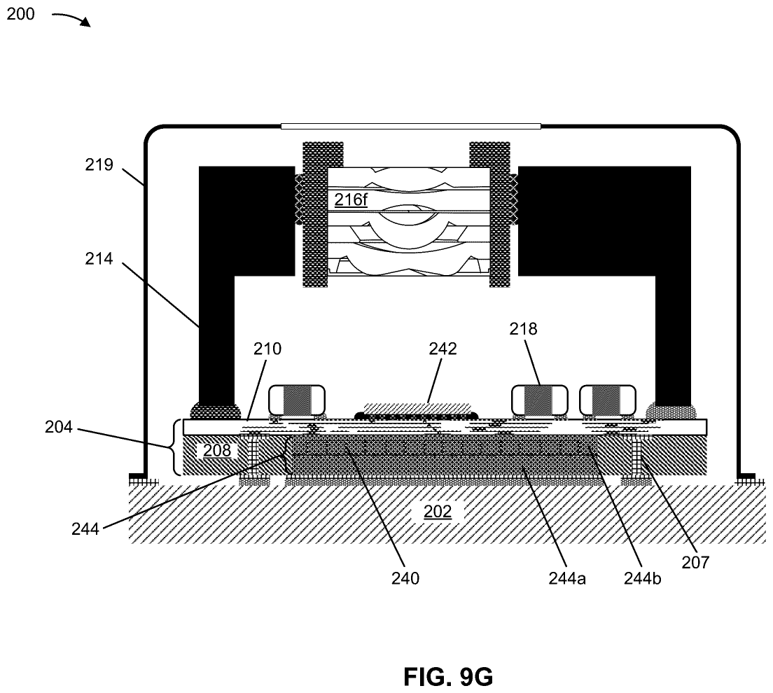

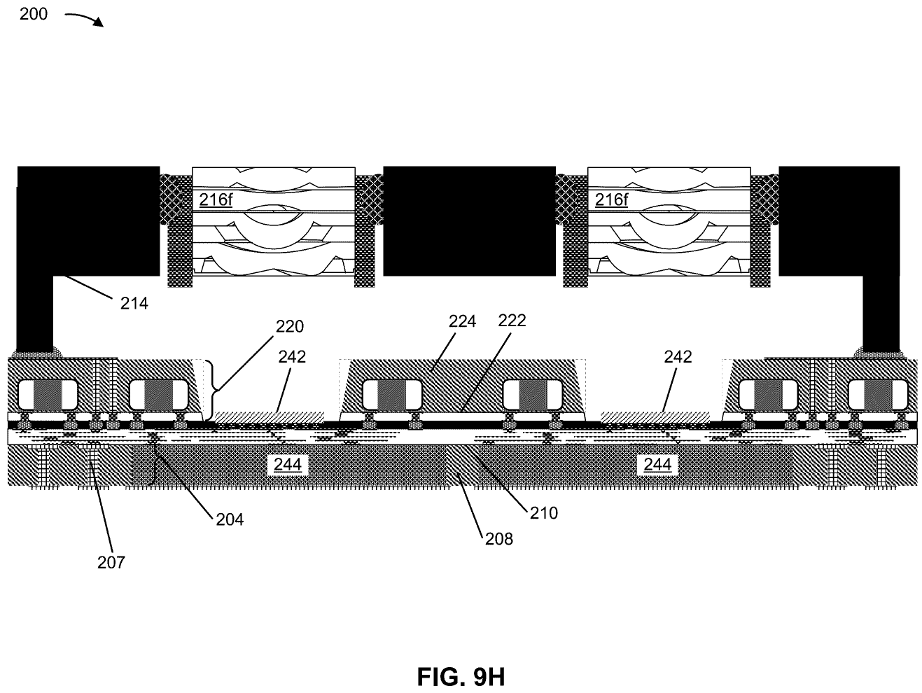

Notably, while the optical package 200 is shown in FIGS. 2A and 2B in the form of an optical transmitter comprising the IC driver chip 206 and the VCSEL chip 212, the optical package 200 may in some implementations comprise an optical receiver. Thus, in some implementations, the optical package 200 may include an optical chip in the form of a sensor chip (e.g., a detector array) rather than, or in addition to, the optical chip in the form of the VCSEL chip 212. Similarly, the optical package 200 may include an electrical chip in the form of a logic chip (e.g., associated with controlling the sensor chip) or a heat spreader rather than, or in addition to, the electrical chip in the form of the IC driver chip 206. Examples of such an optical package 200 are described below with respect to FIGS. 9A-9H.

As indicated above, FIGS. 2A and 2B are provided as an example. Other examples may differ from what is described with regard to FIGS. 2A and 2B. The number and arrangement of components and layers shown in FIGS. 2A and 2B are provided as an example. In practice, there may be additional components or layers, fewer components or layers, different components or layers, differently arranged components or layers, components or layers of different relative sizes than those shown in FIGS. 2A and 2B. Furthermore, two or more components or layers shown in FIGS. 2A and 2B may be implemented within a single component or layer, or a single component or layer shown in FIGS. 2A and 2B may be implemented as multiple, distributed components or layers. Additionally, or alternatively, a set of components or layers (e.g., one or more components or one or more layers) shown in FIGS. 2A and 2B may perform one or more functions described as being performed by another set of components or layers shown in FIGS. 2A and 2B.

As noted above, emitters of the VCSEL chip 212 are electrically connected to the RDL 210. FIG. 3 is a diagram illustrating various techniques by which emitters 212e of the VCSEL chip 212 can be electrically connected to the RDL 210. In one example implementation, a given emitter 212e can be electrically connected to the RDL 210 by a copper (Cu) pillar 302cu and solder 302s that form a solder bond. In another example implementation, a given emitter 212e can be electrically connected to the RDL 210 by a pair of plated gold (Au) bumps 304t and 304b that form an Au—Au diffusion bond. In some implementations, a plated Au bump 306 may have a thickness in a range from approximately 5 microns (μm) to approximately 10 μm. In another example implementation, a given emitter 212e can be electrically connected to the RDL 210 by an Au stud bump 306 that forms an Au—Au diffusion bond. In another example implementation, a given emitter 212e can be electrically connected to the RDL 210 by an Au bump and a silver epoxy that form a silver epoxy bond (not shown in FIG. 3). In another example implementation, a given emitter 212e can be electrically connected to the RDL 210 by an Au bump and solder that form a solder bond (not shown in FIG. 3). Notably, FIG. 3 is provided for illustration and, in practice, multiple (e.g., all) emitters 212e of the VCSEL chip 212 may be electrically connected to the RDL 210 using a single technique. In some implementations, as shown in FIG. 3, an underfill 308 is formed to surround the physical connections formed between the VCSEL chip 212 and the RDL 210.

Notably, while the example shown in FIG. 3 is described in the context of an optical chip in the form of a VCSEL chip 212, these techniques can be similarly applied in association with electrically connecting detectors of a sensor chip (e.g., a detector array included in an optical package 200 in the form of an optical receiver) to the RDL 210 of the FOWLP sub-package 204.

As indicated above, FIG. 3 is provided as an example. Other examples may differ from what is described with regard to FIG. 3. The number and arrangement of components and layers shown in FIG. 3 are provided as an example. In practice, there may be additional components or layers, fewer components or layers, different components or layers, differently arranged components or layers, components or layers of different relative sizes than those shown in FIG. 3. Furthermore, two or more components or layers shown in FIG. 3 may be implemented within a single component or layer, or a single component or layer shown in FIG. 3 may be implemented as multiple, distributed components or layers. Additionally, or alternatively, a set of components or layers (e.g., one or more components or one or more layers) shown in FIG. 3 may perform one or more functions described as being performed by another set of components or layers shown in FIG. 3.

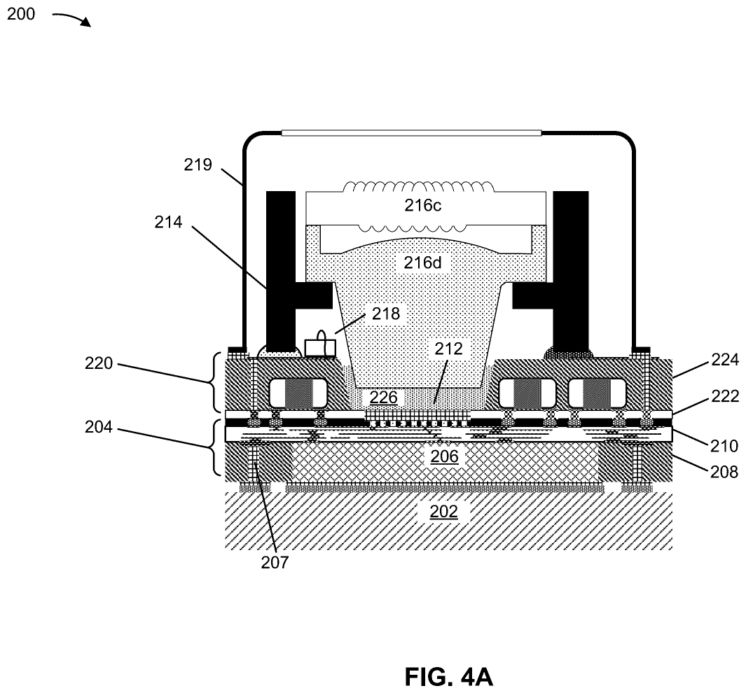

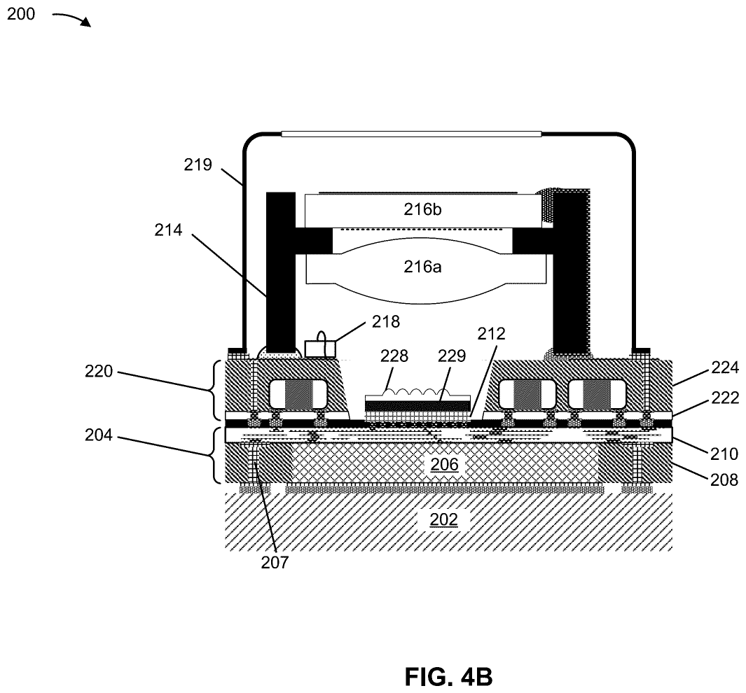

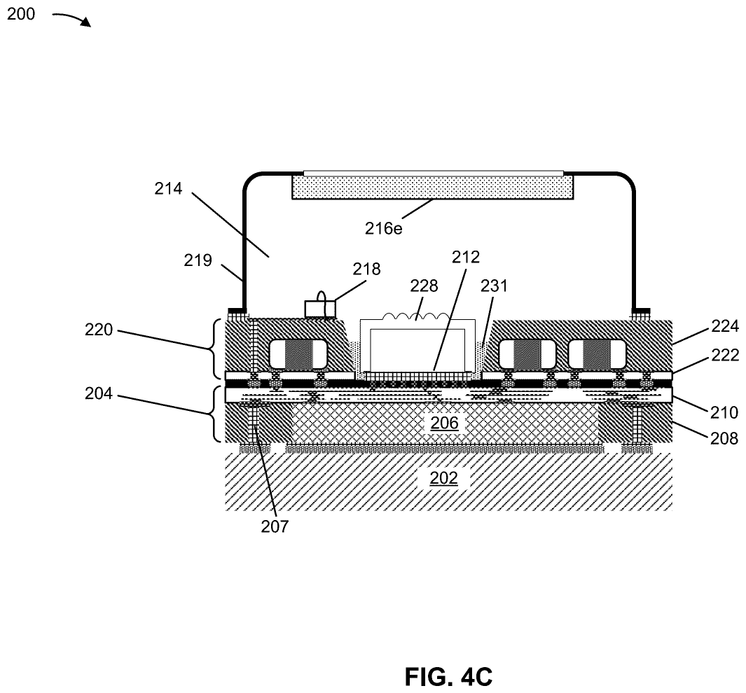

FIGS. 4A-4C are diagrams illustrating example implementations of the optical package 200, in the form of an optical transmitter, including various sets of optical components 216.

In the example implementation shown in FIG. 4A, the optical package 200 includes a roMLA 216c, an elongated collimating lens 216d, and a gel optical interface material (OIM) 226. The gel OIM 226 may include, for example, a soft silicone gel with a refractive index n that is greater than 1 (n>1.0). As shown, the gel OIM 226 may in some implementations at least partially fill a recess in the MIS sub-package 220. As further shown, the gel OIM 226 may at least partially surround the elongated collimating lens 216d within the recess of the MIS sub-package 220. In some implementations, the gel OIM 226 serves to increase light output of the VCSEL chip 212. Further, the gel OIM 226 may reduce or prevent particle contamination on the VCSEL chip 212. Notably, FIG. 4A is provided as an illustrative example, and the optical package 200 shown in FIG. 4A (and other examples described herein) can include different combinations of components. For example, in some implementations, the optical package 200 may include a DOE 206b (rather than the roMLA 216c), the elongated collimating lens 216d, and the gel OIM 226.

In the example implementation shown in FIG. 4B, the optical package 200 includes an MLA 228 mounted over the VCSEL chip 212. In some implementations, the MLA 228 may comprise a plastic material. In some implementations, the MLA 228 can be attached to the VCSEL chip 212 by accurate passive alignment using an OIM 229. In some implementations, the MLA 228 serves to control a dot pitch of an image projected by the optical package 200 and to control a divergence angle of light emitted by emitters of the VCSEL chip 212. In some implementations, the OIM 229 may comprise a cured transparent epoxy, such as cyclo-olefin polymer (COP), or cyclic olefin copolymer (COC), among other examples.

In the example implementation shown in FIG. 4C, the optical package includes an MLA 228 mounted over the VCSEL chip 212. In this example, the MLA 228 is formed to have legs that provide a gap between the MLA 228 and a surface of the VCSEL chip 212. Such an MLA 228 may be used in, for example, an optical package 200 that is a diffuser-type projector. Notably, the MLA 228 can be accurately molded and therefore may be less costly than, for example, an etched gallium arsenide (GaAs) MLA. As indicated in FIG. 4C, the gap between the MLA 228 and the VCSEL chip 212 is defined by a length of the legs of the MLA 228. In some implementations, as illustrated in FIG. 4C, a bottom surface of a leg of the MLA 228 may be uneven such that a shorter portion of the leg is over the VCSEL chip 212, while a longer portion of the leg is not. In some implementations, such a leg structure increases accuracy when placing the MLA 228 during manufacturing. In some implementations, as shown in FIG. 4C, an epoxy 231 (e.g., a non-transparent epoxy) may at least partially surround the MLA 228 within the recess of the MIS sub-package 220. In some implementations, the epoxy 231 serves to bond the MLA 228 to the MIS sub-package 220 or the VCSEL chip 212 (e.g., to hold the MLA 228 in place). In some implementations, the epoxy 231 (e.g., a thin layer of the epoxy 231) is present between the MLA 228 and the VCSEL chip 212, or under the legs of the MLA, to improve bonding. Further, in this example implementation, the optical package 200 need not include a protective coating (e.g., an eye safety coating may not be needed). Alternatively, the optical package 200 may include a protective window 216e.

As indicated above, FIGS. 4A-4C are provided as an example. Other examples may differ from what is described with regard to FIGS. 4A-4C. For example, while FIGS. 4B and 4C are illustrated with a PoP architecture similar to FIG. 2B, the example implementations in FIGS. 4B and 4C are equally possible with a SiP architecture as illustrated in FIG. 2A. The number and arrangement of components and layers shown in FIGS. 4A-4C are provided as an example. In practice, there may be additional components or layers, fewer components or layers, different components or layers, differently arranged components or layers, components or layers of different relative sizes than those shown in FIGS. 4A-4C. Furthermore, two or more components or layers shown in FIGS. 4A-4C may be implemented within a single component or layer, or a single component or layer shown in FIGS. 4A-4C may be implemented as multiple, distributed components or layers. Additionally, or alternatively, a set of components or layers (e.g., one or more components or one or more layers) shown in FIGS. 4A-4C may perform one or more functions described as being performed by another set of components or layers shown in FIGS. 4A-4C.

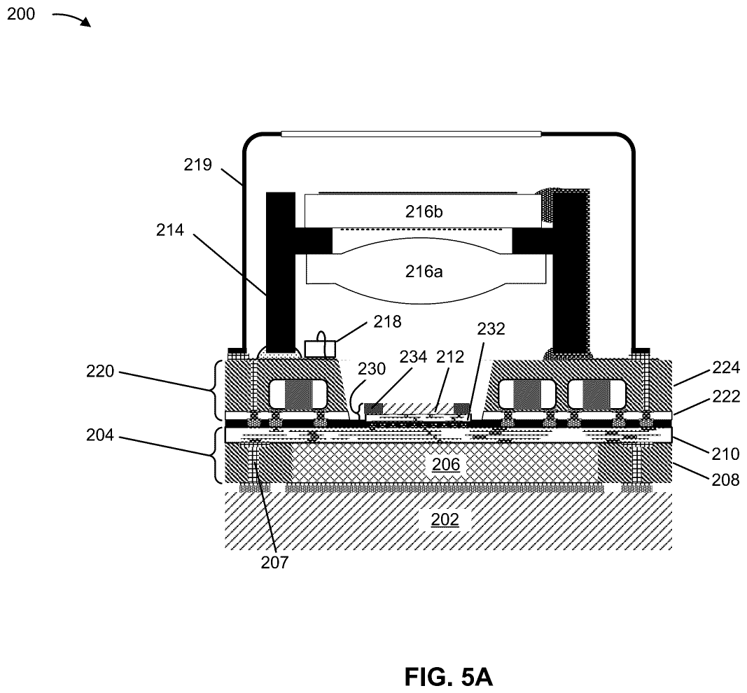

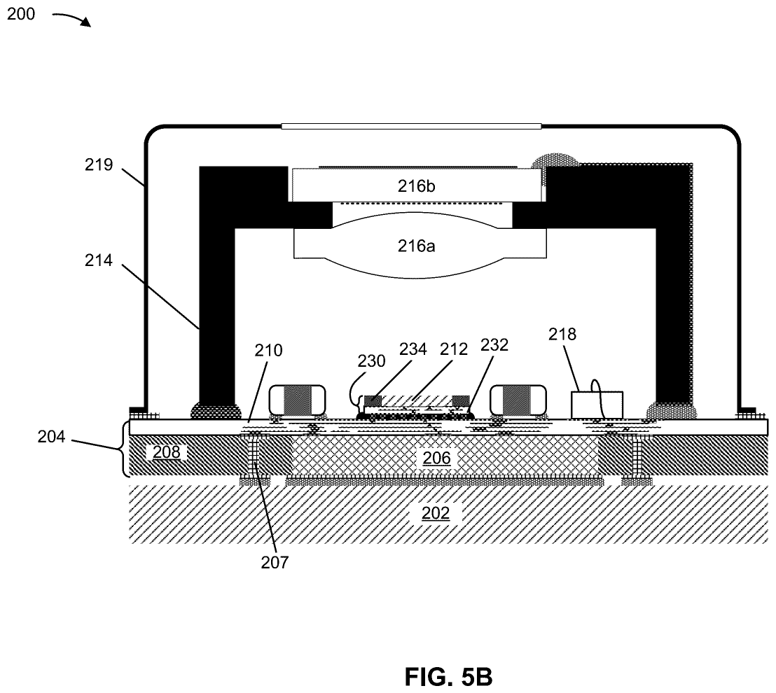

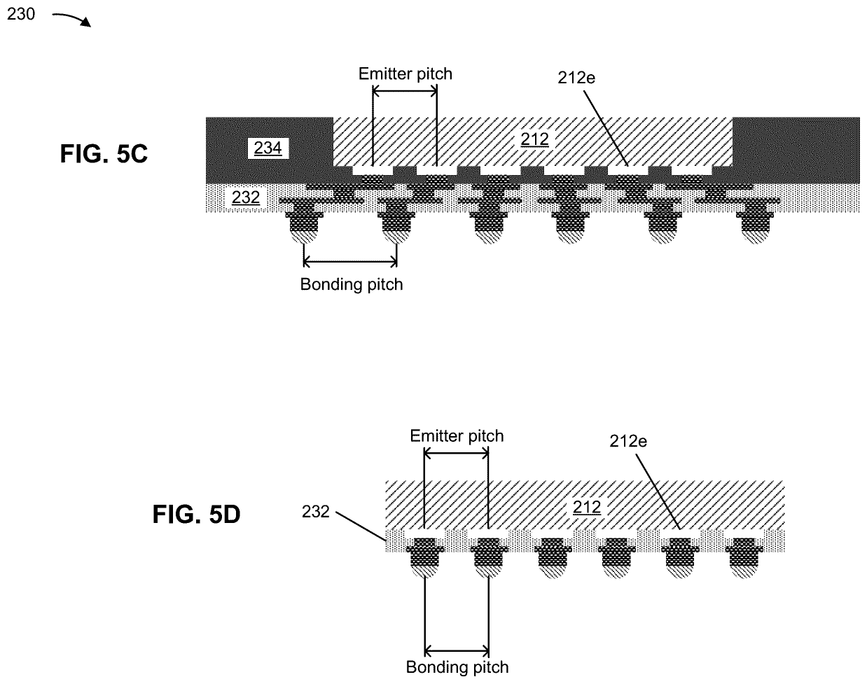

FIGS. 5A-5D are diagrams illustrating example implementations of the optical package 200 in which the VCSEL chip 212 is included in a second sub-package 230 of the optical package 200. In some implementations, as shown in FIGS. 5A and 5B, the VCSEL chip 212 may be included in a sub-package 230. In some implementations, the second sub-package 230 may be an FOWLP sub-package. That is, in some implementations, the VCSEL chip 212 may be included in a second FOWLP sub-package of the optical package 200.

As shown in FIGS. 5A and 5B, when the second sub-package 230 is a FOWLP sub-package, the sub-package 230 may include an RDL 232 and a molded component 234, with the VCSEL chip 212 being embedded in the molded component 234. In some implementations, as shown in FIGS. 5A and 5B, the second sub-package 230 may exclude an IC chip and/or exclude additional discrete circuit components such that the RDL 232 provides (e.g., changes a lateral distribution of) electrical connectivity between the VCSEL chip 212 and the RDL 210. The VCSEL chip 212 may be included in an FOWLP sub-package when, for example, pillars or studs (e.g., Cu pillars, Au studs, or the like) under each emitter of the VCSEL chip 212 that are to form electrical connections with RDL 210 of the FOWLP sub-package 204 are small or dense such that connecting the VCSEL chip 212 to the RDL 210 is impractical or impossible. Here, FOWLP technology can be used to mold the VCSEL chip 212 to form the molded component 234, after which RDL 232 can be formed (e.g., to include two metal layers). This enables the pillars or studs connecting the VCSEL chip 212 to be redistributed or spread (e.g., such that a pitch between pillars or studs is increased) at a bottom surface of the RDL 232, thereby enabling comparatively larger pillar bumping (e.g., Cu-pillar bumping) or stud bumping (e.g., Au-stud bumping) and, therefore, increasing manufacturability. FIG. 5C is a diagram illustrating an example second sub-package 230 in the form of an FOWLP sub-package. As shown in FIG. 5C, the use of FOWLP technology to form the second sub-package 230 (i.e., the sub-package including the VCSEL chip 212 within the molded component 234 on the RDL 232) enables a pitch between bonds to be larger than a pitch between emitters 212e of the VCSEL chip 212, as described above. That is, the use of FOWLP technology provides the RDL 232 that can be designed or configured to provide electrical connections from the molded component 234 (e.g., electrical connections spaced at an emitter pitch of the emitters 212e) on a top surface of the RDL 232 to a desired (e.g., comparatively larger) bonding pitch at a bottom surface of the RDL 232.

Alternatively, in some implementations, the second sub-package 230 may be an FIWLP sub-package. That is, in some implementations, the VCSEL chip 212 may be included in a FIWLP sub-package of the optical package 200. FIG. 5D is a diagram illustrating an example second sub-package 230 in the form of an FIWLP sub-package. As shown in FIG. 5D, the use of FIWLP technology permits a pitch between bonds to be approximately equal to a pitch between emitters 212e of the VCSEL chip 212.

Notably, while the optical devices 200 shown in FIGS. 5A-5D are described in the context of an optical package 200 in the form of an optical transmitter comprising the IC driver chip 206 and the VCSEL chip 212, the optical package 200 may in some implementations comprise an optical receiver in which a sensor chip (e.g., a detector array) is included in the second sub-package 230 of the optical package 200, an example of which is described below with respect to FIG. 9E.

As indicated above, FIGS. 5A-5D are provided as an example. Other examples may differ from what is described with regard to FIGS. 5A-5D. The number and arrangement of components and layers shown in FIGS. 5A-5D are provided as an example. In practice, there may be additional components or layers, fewer components or layers, different components or layers, differently arranged components or layers, components or layers of different relative sizes than those shown in FIGS. 5A-5D. Furthermore, two or more components or layers shown in FIGS. 5A-5D may be implemented within a single component or layer, or a single component or layer shown in FIGS. 5A-5D may be implemented as multiple, distributed components or layers. Additionally, or alternatively, a set of components or layers (e.g., one or more components or one or more layers) shown in FIGS. 5A-5D may perform one or more functions described as being performed by another set of components or layers shown in FIGS. 5A-5D.

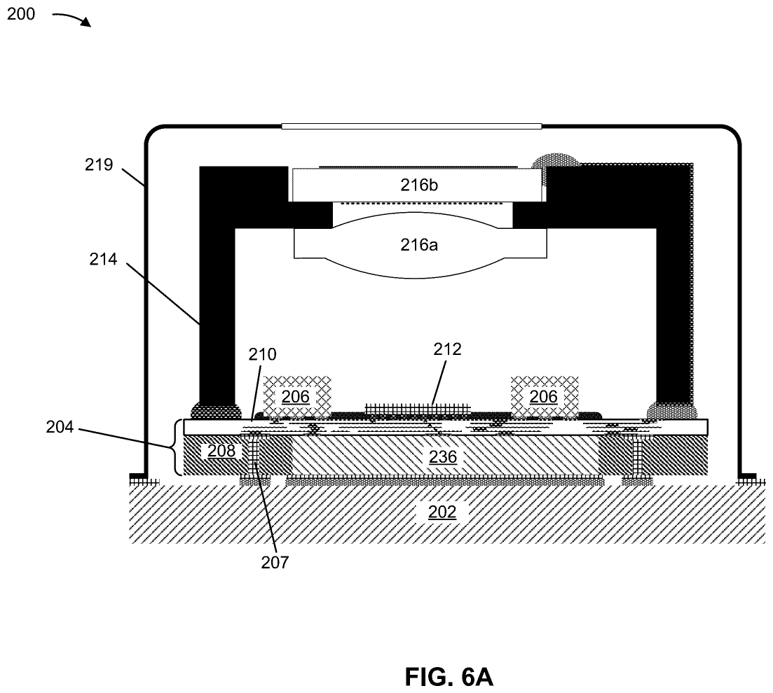

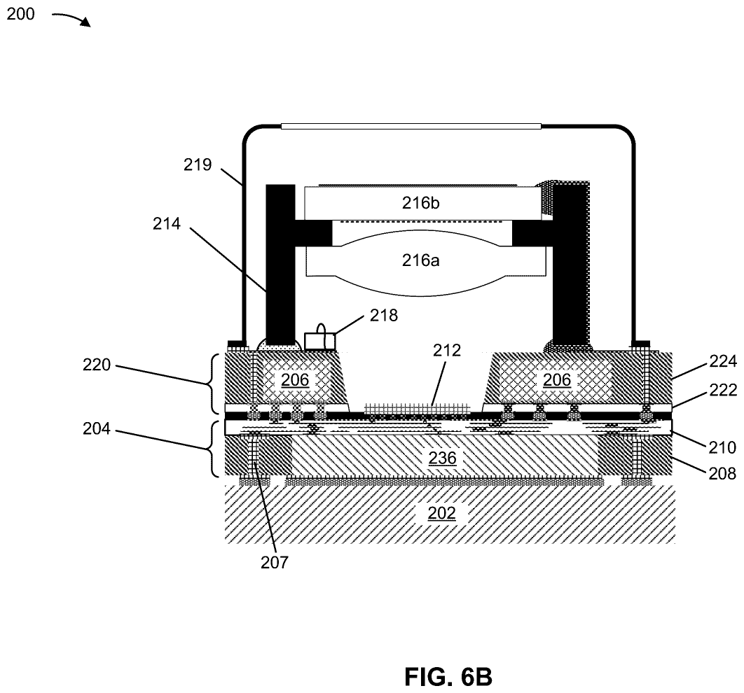

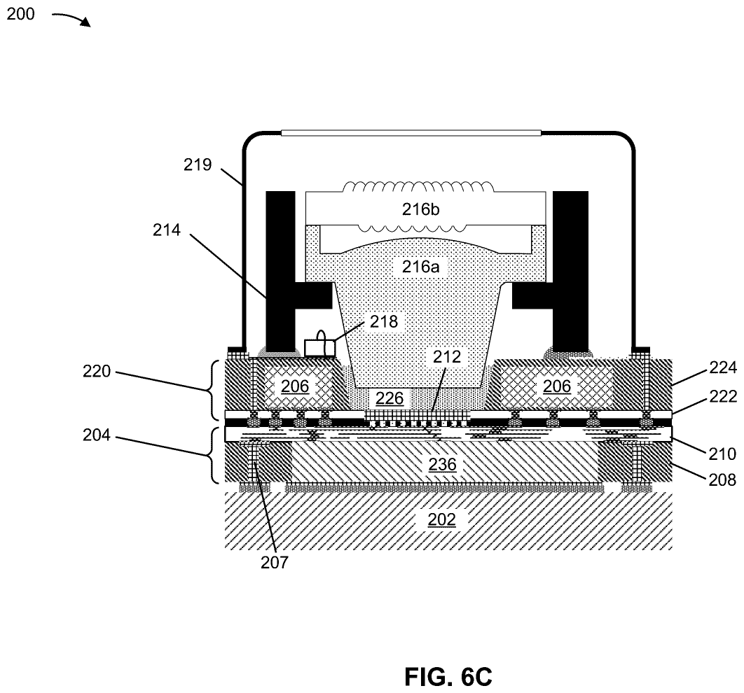

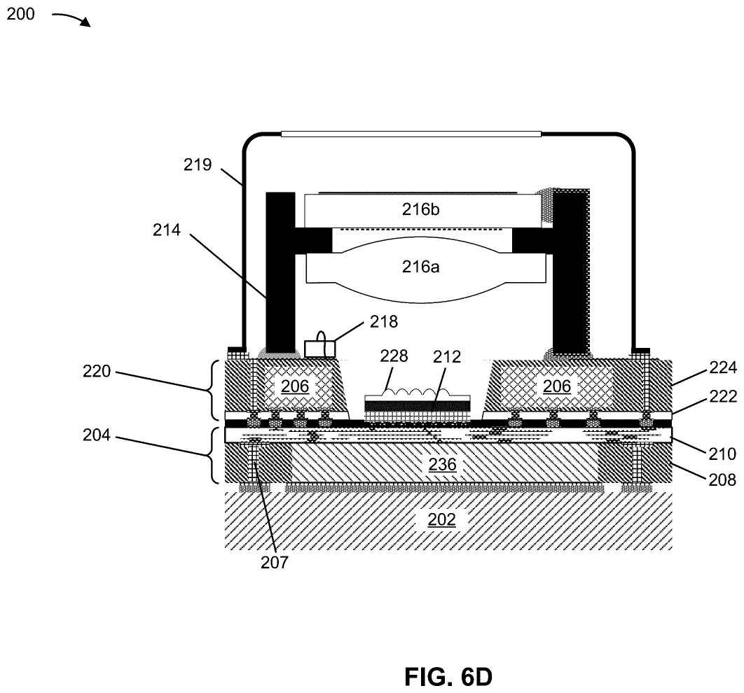

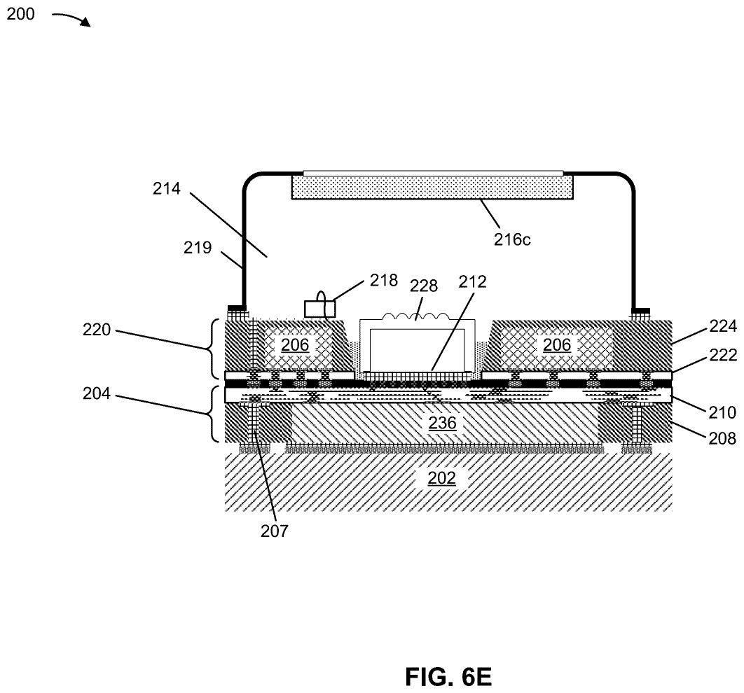

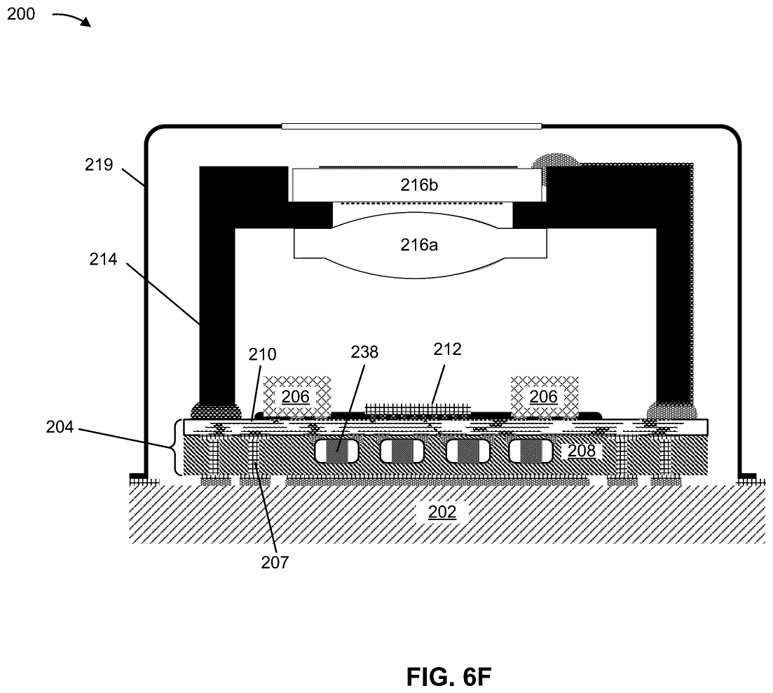

FIGS. 6A-6F are diagrams illustrating example implementations of the optical package 200 in which the FOWLP sub-package 204 includes one or more components other than the IC driver chip 206.

In some implementations, as illustrated in FIGS. 6A-6E, the one or more components may include a capacitor array 236. Thus, in some implementations, the FOWLP sub-package 204 may be formed such that the capacitor array 236 is embedded in the molded component 208 (e.g., rather than the IC driver chip 206). In some implementations, as illustrated in FIG. 6A, such an optical package 200 includes one or more IC driver chips 206 that are mounted on the FOWLP sub-package 204. Additionally, or alternatively, as illustrated in FIGS. 6B-6E, one or more IC driver chips 206 may be embedded in the MIS sub-package 220 that is mounted over the FOWLP sub-package 204. In some implementations, an FOWLP sub-package 204 including the capacitor array 236 may have a better thermal performance than an FOWLP sub-package 204 including the IC driver chip 206.

In some implementations, as illustrated in FIG. 6F, the one or more components may include one or more discrete circuit components 238 (e.g., one or more surface mounted devices (SMDs)), such as one or more discrete capacitors, or one or more thermistors, among other examples. Such an implementation may be advantageous when, for example, a thermistor is embedded in the molded component 208, which provides improved temperature control. Further, such an implementation may reduce a circuit path length between the IC driver chip 206 and the VCSEL chip 212, which may improve performance of the VCSEL chip 212.

Notably, while the optical devices 200 shown in FIGS. 6A-6F are in the form of an optical transmitter comprising the IC driver chip 206 and the VCSEL chip 212, the optical package 200 may in some implementations comprise an optical receiver including a logic chip (and optionally a heat spreader) and a sensor chip, where a component other than the logic chip (and the heat spreader) is embedded in the FOWLP sub-package 204, an example of which is described below with respect to FIG. 9F.

As indicated above, FIGS. 6A-6F are provided as an example. Other examples may differ from what is described with regard to FIGS. 6A-6F. The number and arrangement of components and layers shown in FIGS. 6A-6F are provided as an example. In practice, there may be additional components or layers, fewer components or layers, different components or layers, differently arranged components or layers, components or layers of different relative sizes than those shown in FIGS. 6A-6F. Furthermore, two or more components or layers shown in FIGS. 6A-6F may be implemented within a single component or layer, or a single component or layer shown in FIGS. 6A-6F may be implemented as multiple, distributed components or layers. Additionally, or alternatively, a set of components or layers (e.g., one or more components or one or more layers) shown in FIGS. 6A-6F may perform one or more functions described as being performed by another set of components or layers shown in FIGS. 6A-6F.

FIG. 7 is a diagram illustrating an example implementation of the optical package 200 in which the FOWLP sub-package 204 includes an IC driver chips 206 comprising multiple independent IC driver chips. For example, as illustrated in FIG. 7, the FOWLP sub-package 204 may include an IC driver chip 206 comprising a first IC driver chip 206a and a second IC driver chip 206b, with the second IC driver chip 206b being stacked on the first IC driver chip 206a. In some implementations, the independent IC driver chips of the IC driver chip 206 can be stacked and one or more through-silicon-vias (TSVs) 240 can be used to provide electrical connection. For example, as shown in FIG. 7, the IC driver chip 206a and the IC driver chip 206b can be stacked, and a set of TSVs 204 may be formed in the IC driver chip 206b (e.g., the upper portion of the IC driver chip 206) to permit the IC driver chip 206a (i.e., the lower portion of the IC driver chip 206) can be electrically connected to the RDL 210 by a set of TSVs 240 formed in the IC driver chip 206b. In some implementations, an IC driver chip 206 comprising a stack of two or more independent IC driver chips 206 in this manner may serve to further reduce a size of the optical package 200.

Notably, while the optical package 200 shown in FIG. 7 is in the form of an optical transmitter comprising the IC driver chip 206 and the VCSEL chip 212, the optical package 200 may in some implementations comprise an optical receiver including a logic chip and a sensor chip, where the logic chip includes multiple independent logic chips, an example of which is described below with respect to FIG. 9G.

As indicated above, FIG. 7 is provided as an example. Other examples may differ from what is described with regard to FIG. 7. The number and arrangement of components and layers shown in FIG. 7 are provided as an example. In practice, there may be additional components or layers, fewer components or layers, different components or layers, differently arranged components or layers, components or layers of different relative sizes than those shown in FIG. 7. Furthermore, two or more components or layers shown in FIG. 7 may be implemented within a single component or layer, or a single component or layer shown in FIG. 7 may be implemented as multiple, distributed components or layers. Additionally, or alternatively, a set of components or layers (e.g., one or more components or one or more layers) shown in FIG. 7 may perform one or more functions described as being performed by another set of components or layers shown in FIG. 7.

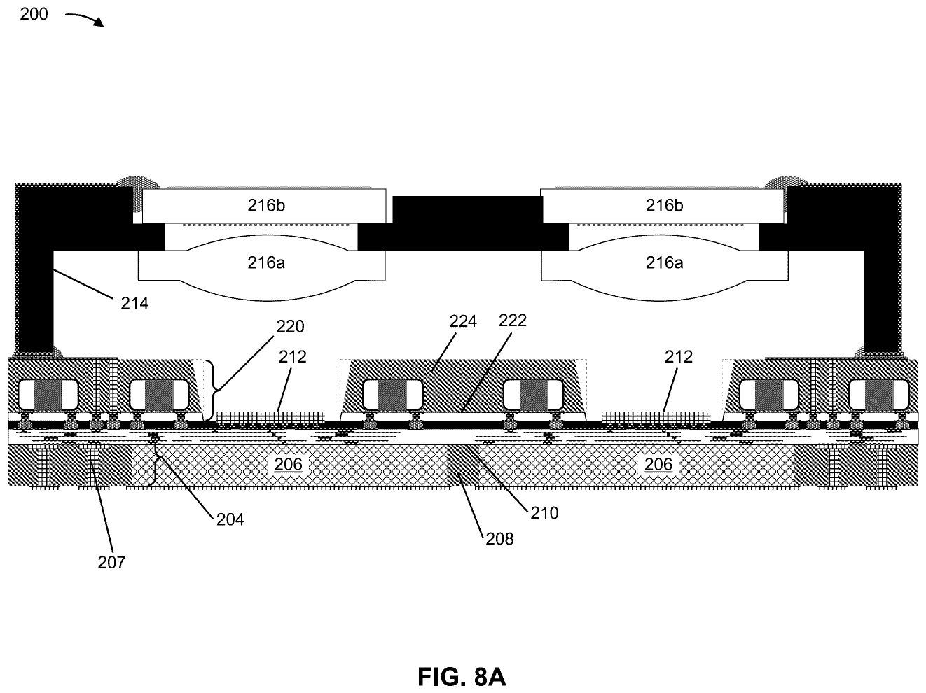

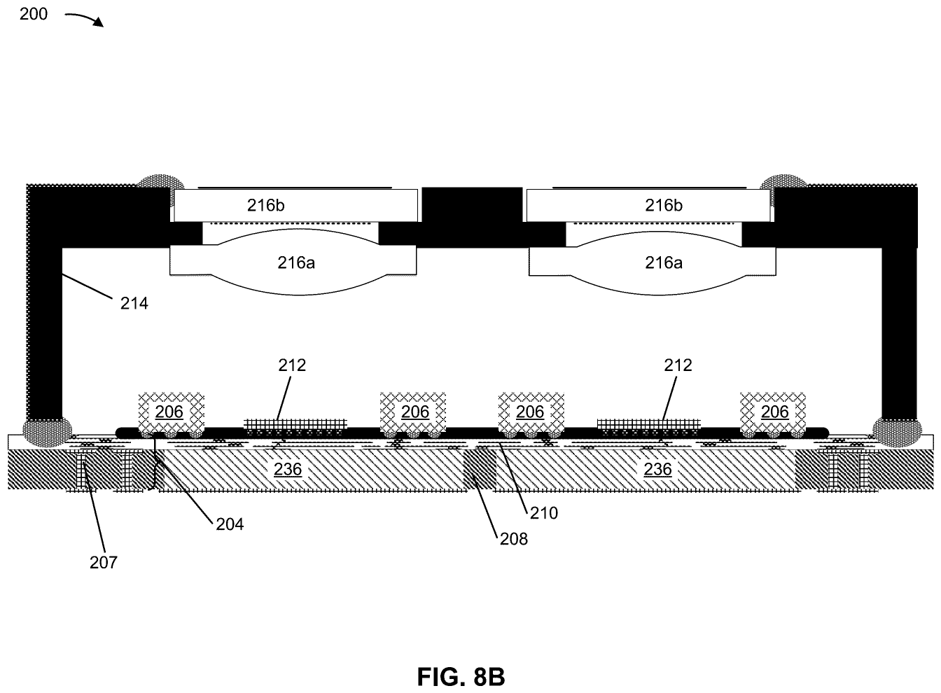

In some implementations, the optical package 200 is a multi-chip module including multiple VCSEL chips 212. For example, the optical package 200 may be a multi-chip module projector including multiple VCSEL chips 212. FIGS. 8A and 8B are diagrams illustrating example implementations of optical packages 200 including multiple VCSEL chips 212 to form a multi-chip module. In some implementations, the use of an FOWLP-based PoP architecture (e.g., as shown in FIG. 8A) or an FOWLP-based SiP architecture (e.g., as shown in FIG. 8B) for the optical package 200 including multiple VCSEL chips 212 may reduce a size of the multi-chip module (e.g., as compared to a conventional multi-chip module).

Notably, while the optical package 200 shown in FIG. 8 is in the form of an optical transmitter comprising multiple VCSEL chips 212, the optical package 200 may in some implementations comprise an optical receiver including multiple sensor chips, an example of which is described below with respect to FIG. 9H.

As indicated above, FIGS. 8A and 8B are provided as an example. Other examples may differ from what is described with regard to FIGS. 8A and 8B. The number and arrangement of components and layers shown in FIGS. 8A and 8B are provided as an example. In practice, there may be additional components or layers, fewer components or layers, different components or layers, differently arranged components or layers, components or layers of different relative sizes than those shown in FIGS. 8A and 8B. Furthermore, two or more components or layers shown in FIGS. 8A and 8B may be implemented within a single component or layer, or a single component or layer shown in FIGS. 8A and 8B may be implemented as multiple, distributed components or layers. Additionally, or alternatively, a set of components or layers (e.g., one or more components or one or more layers) shown in FIGS. 8A and 8B may perform one or more functions described as being performed by another set of components or layers shown in FIGS. 8A and 8B.

As noted above, the optical package 200 may in some implementations include an optical receiver. FIGS. 9A-9H are diagrams illustrating various example implementations of the optical package 200 in the form of an optical receiver that includes an FOWLP sub-package 204 comprising an RDL 210 on a molded component 208, and an optical chip, in the form of a sensor chip 242, over the FOWLP sub-package 204.

As shown in FIGS. 9A and 9B, the optical package 200 may in some implementations include an optical chip in the form of the sensor chip 242, an electrical chip in the form of a logic chip 244, and a set of optical lenses 216f (e.g., one or more lenses to provide image correction) supported by the package housing 214. As shown in FIGS. 9A and 9B, the logic chip 244 may in some implementations be embedded in the molded component 208 of the FOWLP sub-package 204.

As shown in FIGS. 9C and 9D, the optical package 200 may in some implementations further include a heat spreader 246. In such an implementation, as shown in FIGS. 9C and 9D, the heat spreader 246 may be embedded in the molded component 208 of the FOWLP sub-package 204, the logic chip 244 may be mounted on the FOWLP sub-package 204, and the sensor chip 242 may be mounted on the logic chip 244.

The sensor chip 242 includes a component configured to receive light (e.g., via the package housing 214 and the set of optical lens 216f supported by the package housing 214) and convert the received light from one or more optical signals to an electrical signals. For example, the sensor chip 242 may include an array of photodetectors (e.g., a 1D detector array or a 2D detector array) comprising one or more single-photon avalanche photodiodes (SPADs), one or more silicon photomultipliers (SiPMs), or the like. The logic chip 244 is a component associated with controlling operation of the sensor chip 242 and/or receiving the one or more electrical signals provided by the sensor chip 242. In some implementations, the sensor chip 242 may be electrically connected to the logic chip 244 via the RDL 210 (and via the heat spreader 246 in the examples shown in FIGS. 9C and 9D). In some implementations, such as those shown in FIGS. 9A and 9B, detectors of the sensor chip 242 may be electrically connected to the RDL 210 using one or more techniques as described above with respect to FIG. 3.

FIGS. 9A and 9C are diagrams in which an optical package 200 in the form of the optical receiver utilizes the SiP architecture as described above with respect to FIG. 2A. In some implementations, the optical receiver with the SiP architecture provides similar advantages to those described above with respect to FIG. 2A.

FIGS. 9B and 9D are diagrams in which an optical package 200 in the form of the optical receiver utilizes the PoP architecture as described above with respect to FIG. 2B. In some implementations, the optical receiver with the PoP architecture provides similar advantages to those described above with respect to FIG. 2B.

FIG. 9E is a diagram of an optical package 200 in the form of the optical receiver in which the sensor chip 242 is included in a second sub-package 230 of the optical package 200. In some implementations, the sensor chip 242 may be included in the second sub-package 230 in a manner similar to any of those illustrated and described above with respect to FIGS. 5A-5D.

FIG. 9F is a diagram of an optical package 200 in the form of the optical receiver in which a component other than the logic chip 244 is embedded in the FOWLP sub-package 204. For example, in FIG. 9F, the logic chip 244 (comprising two independent logic chips 244) is embedded in the molded component 224 of the MIS sub-package 220, and a capacitor array 236 is included in the molded component 208 of the FOWLP sub-package 204. In some implementations, the optical package 200 in the form of the optical receiver may have an architecture similar to any those illustrated and described above with respect to FIGS. 6A-6F.

FIG. 9G is a diagram of an optical package 200 in the form of the optical receiver in which the logic chip 244 includes multiple independent logic chips 244—logic chip 244a and logic chip 244b. In some implementations, the independent logic chips 244a and 244b may be positioned or electrically connected in a manner similar to that illustrated and described above with respect to FIG. 7.

FIG. 9H is a diagram of an optical package 200 in the form of an optical receiver comprising multiple sensor chips 242 such that the optical package 200 is a multi-chip module. In some implementations, the optical package 200 in the form of the optical receiver including multiple sensor chips 242 may have an architecture similar to either of those illustrated and described above with respect to FIGS. 8A and 8B.

Notably, while FIGS. 9E-9H illustrate examples in which the optical package 200 does not include a heat spreader 246, an architecture similar to any of those shown in FIGS. 9E-9H can be utilized for an optical packages 200 including the heat spreader 246.

As indicated above, FIGS. 9A-9H are provided as an example. Other examples may differ from what is described with regard to FIGS. 9A-9H. The number and arrangement of components and layers shown in FIGS. 9A-9H are provided as an example. In practice, there may be additional components or layers, fewer components or layers, different components or layers, differently arranged components or layers, components or layers of different relative sizes than those shown in FIGS. 9A-9H. Furthermore, two or more components or layers shown in FIGS. 9A-9H may be implemented within a single component or layer, or a single component or layer shown in FIGS. 9A-9H may be implemented as multiple, distributed components or layers. Additionally, or alternatively, a set of components or layers (e.g., one or more components or one or more layers) shown in FIGS. 9A-9H may perform one or more functions described as being performed by another set of components or layers shown in FIGS. 9A-9H.

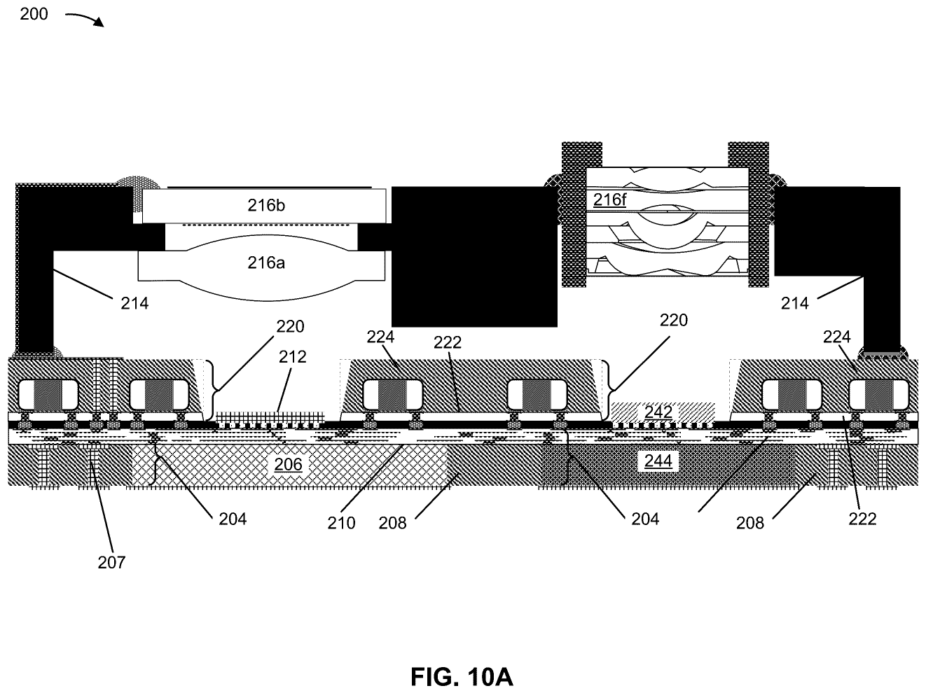

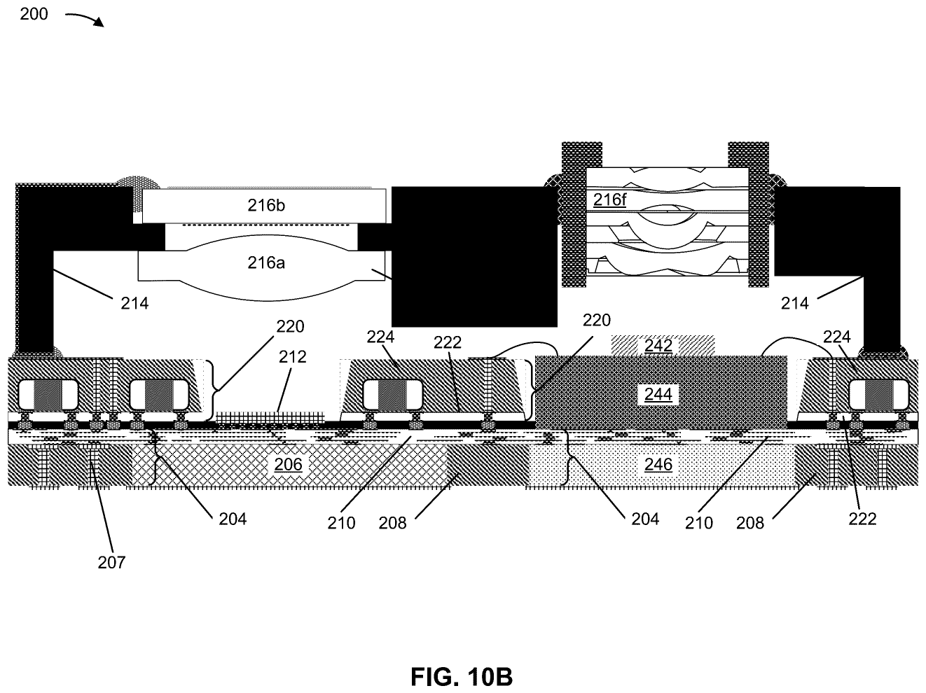

In some implementations, the optical package 200 is a 3D sensing module including a projector and a detector. FIGS. 10A and 10B are diagrams illustrating example implementations of optical packages 200 that form a 3D sensing module. As shown in FIGS. 10A and 10B, components on a left side of the optical package 200 form an optical transmitter (e.g., a projector), while components on a right side of the optical package 200 form an optical receiver In some implementations, the use of an FOWLP-based PoP architecture (e.g., as shown in FIG. 10A) or an FOWLP-based SiP architecture (e.g., as shown in FIG. 10B) for the optical package 200 that forms the 3D sensing module may provide similar advantages as those described above with respect to FIGS. 2A and 2B, respectively.

As indicated above, FIGS. 10A and 10B are provided as an example. Other examples may differ from what is described with regard to FIGS. 10A and 10B. The number and arrangement of components and layers shown in FIGS. 10A and 10B are provided as an example. In practice, there may be additional components or layers, fewer components or layers, different components or layers, differently arranged components or layers, components or layers of different relative sizes than those shown in FIGS. 10A and 10B. Furthermore, two or more components or layers shown in FIGS. 10A and 10B may be implemented within a single component or layer, or a single component or layer shown in FIGS. 10A and 10B may be implemented as multiple, distributed components or layers. Additionally, or alternatively, a set of components or layers (e.g., one or more components or one or more layers) shown in FIGS. 10A and 10B may perform one or more functions described as being performed by another set of components or layers shown in FIGS. 10A and 10B.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical package, comprising:
a fan-out-wafer-level-packaging (FOWLP) sub-package including a redistribution layer (RDL) on a molded component including an electrical chip;
an optical chip over the FOWLP sub-package, the optical chip being electrically connected to the RDL, wherein an area of a surface of the RDL is larger than an area of a surface of the optical chip; and
a package housing over the optical chip, wherein light to be received or transmitted by the optical chip is to pass through the package housing.

2. The optical package of claim 1, further comprising a molded interconnect substrate (MIS) sub-package over the FOWLP sub-package, the MIS sub-package including a second RDL and a second molded component.

3. The optical package of claim 1, wherein the package housing supports a set of optical components arranged over the VCSEL chip, the set of optical components including at least one of a diffractive optical element, a collimating lens, a microlens array (MLA), a rotational offset MLA, a glass, a protective coating, or a protective window.

4. The optical package of claim 1, wherein the package housing is attached to the FOWLP sub-package.

5. The optical package of claim 1, wherein the package housing is attached to a molded interconnect substrate sub-package that is over the FOWLP sub-package.

6. The optical package of claim 1, further comprising one or more components mounted on the FOWLP sub-package.

7. The optical package of claim 1, wherein a component the optical chip is electrically connected to the RDL by one of:
a pair of plated gold (Au) bumps with an Au—Au diffusion bond,
a copper (Cu) pillar with a solder bond,
an Au stud bump with an Au—Au diffusion bond,
an Au bump with a silver epoxy bond, or
an Au bump with a solder bond.

8. The optical package of claim 1, further comprising a gel optical interface material over the optical chip within a recess in a molded interconnect substrate sub-package that is on the FOWLP sub-package.

9. The optical package of claim 1, further comprising a microlens array mounted over the optical chip.

10. The optical package of claim 1, wherein the optical chip is included in a second FOWLP sub-package, the second FOWLP sub-package comprising a second RDL and a second molded component, wherein the optical chip is embedded in the second molded component.

11. The optical package of claim 1, wherein the optical package is a multi-chip module including multiple optical chips.

12. The optical package of claim 1, wherein the optical package is a three-dimensional sensing module including the optical chip.

13. The optical package of claim 1, wherein the electrical chip comprises at least one of an integrated circuit (IC) driver chip, a capacitor array, a discrete circuit component, a heat spreader, or a logic chip.

14. The optical package of claim 1, wherein the optical chip comprises a vertical-cavity surface-emitting laser (VCSEL) chip or a sensor chip.

15. An optical package, comprising:
a fan-out-wafer-level-packaging (FOWLP) sub-package including a first redistribution layer (RDL) on a first molded component;
a molded interconnect substrate (MIS) sub-package over the FOWLP sub-package, the MIS sub-package including a second RDL on a second molded component;
an optical chip over the FOWLP sub-package, the optical chip being electrically connected to the first RDL, wherein an area of the RDL is larger than an area of the optical chip; and
a package housing over the VCSEL chip, wherein light to be received or transmitted by the optical chip is to pass through the package housing.

16. The optical package of claim 15, wherein the package housing is attached to the FOWLP sub-package or to the MIS sub-package.

17. The optical package of claim 15, wherein the optical chip is a vertical-cavity surface-emitting laser (VCSEL) chip, and an emitter of the VCSEL chip is electrically connected to the RDL by one of:
a pair of plated thick gold (Au) bumps with an Au—Au diffusion bond,
a copper (Cu) pillar with a solder bond,
an Au stud bump with an Au—Au diffusion bond,
an Au bump with a silver epoxy bond, or
an Au bump with a solder bond.

18. The optical package of claim 15, wherein the optical chip is included in a second FOWLP sub-package, the second FOWLP sub-package comprising a second RDL and a second molded component, wherein the optical chip is embedded in the second molded component.

19. An optical package, comprising:
a fan-out-wafer-level-packaging (FOWLP) sub-package including a redistribution layer (RDL) on a molded component, wherein the molded component includes at least one electrical chip;
a vertical-cavity surface-emitting laser (VCSEL) chip over the FOWLP sub-package, the VCSEL chip being electrically connected to the electrical chip through the RDL, wherein a size of the RDL is larger than a corresponding size of the VCSEL chip; and
a package housing over the VCSEL chip, wherein light to be transmitted by the VCSEL chip is to pass through the package housing.

20. The optical package of claim 19, further comprising a molded interconnect substrate (MIS) sub-package over the FOWLP sub-package, the MIS sub-package including a second RDL and a second molded component.
